(19) United States
(12) Patent Application Publication
(10) Pub. No.: US 2018/0082868 A1
(43) Pub. Date: Mar. 22, 2018

(54) GRAVITY FORCE COMPENSATION PLATE FOR UPSIDE DOWN BALL GRID ARRAY

(71) Applicant: ALCATEL-LUCENT CANADA INC., Ottawa (CA)

(72) Inventors: Paul J. BROWN, Wakefield (CA); Alex L. CHAN, Ottawa (CA); Robert D'Amico, Ottawa (CA)

(73) Assignee: ALCATEL-LUCENT CANADA INC.

(21) Appl. No.: 15/659,258

(22) Filed: Jul. 25, 2017

Related U.S. Application Data
(60) Provisional application No. 62/397,140, filed on Sep. 20, 2016.

(51) Int. Cl. H01L 21/67; B23K 3/06; H05K 3/32; H01L 21/50; H05K 3/34

(52) U.S. Cl. CPC H01L 21/67138; B23K 3/0623; H05K 3/3436; H01L 21/50; H05K 3/32

(57) ABSTRACT

An apparatus configured to temporarily support a Ball Grid Array (BGA) component against a printed circuit board (PCB) during a manufacturing reflow operation, the apparatus including a support plate sized to fit over the BGA and having one or more mounting holes external to the periphery of the Ball Grid Array component, a retaining member for each mounting hole, passing through said mounting hole, a resilient biasing member for each retaining member, wherein the resilient biasing member urges the support plate against the BGA component from below the BGA component such that the BGA component is urged against the PCB.

### RELATED APPLICATIONS

This application claims the benefit of U.S. Provisional Application No. 62/397,140 filed Sep. 20, 2016, which is hereby incorporated by reference for all purposes as if fully set forth herein.

### TECHNICAL FIELD

The invention relates to integrated circuits. More particularly, the invention relates to a method and apparatus for holding a BGA chip in place during reflow soldering.

### SUMMARY

A brief summary of various embodiments is presented below. Some simplifications and omissions may be made in the following summary, which is intended to highlight and introduce some aspects of the various embodiments, but not to limit the scope of the invention. Detailed descriptions of embodiments adequate to allow those of ordinary skill in the art to make and use the inventive concepts will follow in later sections.

Various embodiments include an apparatus configured to temporarily support a Ball Grid Array (BGA) component against a printed circuit board (PCB) during a manufacturing reflow operation, the apparatus including a support plate sized to fit over the BGA and having one or more mounting holes external to the periphery of the Ball Grid Array component, a retaining member for each mounting hole, passing through said mounting hole, a resilient biasing member for each retaining member, wherein the resilient biasing member urges the support plate against the BGA component from below the BGA component such that the BGA component is urged against the PCB.

The support plate and resilient biasing member may create a cumulative weight, and wherein the support plate is urged against the BGA component with a force greater than the cumulative weight.

The resilient biasing member may include a spring.

The retaining member may include a bolt having a shoulder and the resilient member is mounted on the retaining member.

The retaining member may be coupled to the PCB by a fastening member.

The support plate may have the shape of a window frame.

The support plate may include a plurality of apertures to decrease thermal resistance thereof.

Various embodiments also include an apparatus to support a semiconductor chip mounted to a printed circuit board (PCB) during a manufacturing process thereof, the apparatus including a support plate configured to counter a weight of the semiconductor chip, a plurality of fastening members on a first side of the PCB, a plurality of support pins extending through the PCB and coupled to the plurality of fastening members, and a biasing member connected to the plurality of support pins and configured to urge the support plate into contact with the semiconductor chip on a second side of the PCB.

The semiconductor chip may be mounted to a bottom side of the PCB such that gravity pulls the semiconductor chip away from the PCB.

The biasing member may urge the support plate and semiconductor chip upwards with a force greater than a gravitational force acting on the semiconductor chip.

The biasing member may be a leaf spring.

The fastening members may be C-clips or cotter pins.

Various embodiments also include a method of mounting a BGA on a printed circuit board (PCB), including mounting a BGA on a side of a PCB, determining a size of a resilient biasing member based on a weight of a support plate to be secured to the BGA; and securing the support plate to the BGA and to the PCB using the resilient biasing member which is configured to urge the support plate against the BGA such that the BGA is urged against the PCB.

The method may include determining a negative gravity force to urge the support plate towards the PCB, wherein the negative gravity force is greater than the weight of the support plate and the BGA.

The method may include securing the support plate to the BGA is performed using a retaining member.

The retaining member may include a bolt having a shoulder wherein the resilient member is mounted on the retaining member.

### BRIEF DESCRIPTION OF THE DRAWINGS

Additional objects and features of the invention will be more readily apparent from the following detailed description and appended claims when taken in conjunction with the drawings. Although several embodiments are illustrated and described, like reference numerals identify like parts in each of the figures, in which:

FIG. 1 illustrates a cross-sectional view of a printed circuit board having a ball grid array mounted to the bottom side thereof via reflowed solder balls in accordance with embodiments described herein;

FIGS. 2A-2C illustrate top views of support plates in accordance with embodiments described herein;

FIG. 3 illustrates a cross-sectional view of a PCB and support plate in accordance with embodiments described herein;

FIG. 4 illustrates a bolt having a shoulder and a spring attached thereto in accordance with embodiments described herein;

FIGS. 5A-5C illustrate embodiments of leaf spring biasing members in accordance with embodiments described herein; and

FIGS. 6A and 6B illustrate an additional fastening assemblies according to embodiments described herein.

### DETAILED DESCRIPTION

It should be understood that the figures are merely schematic and are not drawn to scale. It should also be understood that the same reference numerals are used throughout the figures to indicate the same or similar parts.

The descriptions and drawings illustrate the principles of various example embodiments. It will thus be appreciated that those skilled in the art will be able to devise various arrangements that, although not explicitly described or shown herein, embody the principles of the invention and are included within its scope. Furthermore, all examples recited herein are principally intended expressly to be for pedagogical purposes to aid the reader in understanding the principles of the invention and the concepts contributed by the inventor(s) to furthering the art, and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments can be combined with one or more other embodiments to form new embodiments. Descriptors such as “first,” “second,” “third,” etc., are not meant to limit the order of elements discussed, are used to distinguish one element from the next, and are generally interchangeable. Values such as maximum or minimum may be predetermined and set to different values based on the application.

When steps of manufacture, process of using, or other method steps are described or claimed, the order of steps given is not constrained by the order presented, and may vary.

Printed circuit boards (PCBs) may have surface mount components mounted on both sides of the PCB. In some manufacturing processes a two-pass reflow operation may be used. On a first pass one side of the PCB may face upward as the components to be soldered are placed on that side of the PCB. Components may include a ball grid array (BGA) or other semiconductor device. Upon completion of a reflow phase, these components are secured to the PCB by the soldered connections. Boards of today are ever more complex, and chips may be mounted on both sides of a PCB to maximize PCB efficiency. A second pass may have the opposite side of the PCB facing upwards, with components to be soldered placed on that face. To perform such a task, a PCB may be turned over so that additional components and chips may be mounted to the top side of the PCB. As a result, components that were previously mounted on the top are now on the bottom. A second reflow operation is then performed that may be termed upside down reflow. During a reflow operation to solder components to the top side of the board, components on the bottom may become loose and electrical connections of those components to the board may open from a force of gravity pulling on those components, as solder joints that connect these components become weaker.

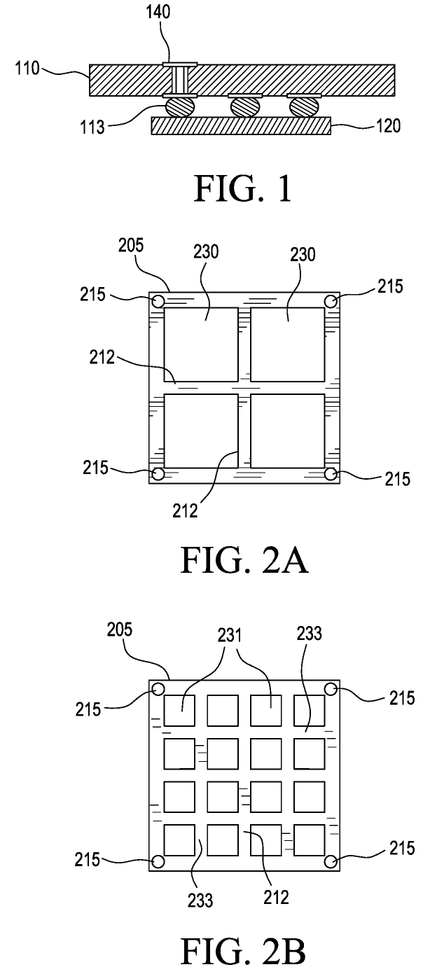

FIG. 1 illustrates a cross-sectional view of a PCB 110 having a BGA 120 mounted to one side thereof via reflowed solder balls 113 in accordance with embodiments described herein. This is a position the BGA 120 experiences during the second upside down reflow phase. A PCB via 140 or a plurality thereof may be disposed in the PCB 110 to connect devices or circuits disposed on either side of the PCB 110.

During testing, production runs have caused open solder connections after the second reflow operation on some of the pins of the BGAs attached on the first pass. It is desirable to provide a means to remedy this occurrence. One restriction for not allowing certain components to be on the “bottom” side of the board (i.e., the side which will see a second reflow operation while upside down during the top side assembly) has been the weight of the components which may cause the component to fall off.

Another situation has been found whereby, heavy BGA packages that are near the limit of what can be supported in upside down reflow lose certain connections through failure of the solder joint. Analysis suggests that pin failures are localized due to local differences in expansion related to mixed PCB interconnect structures, leading to stresses sufficient to break solder bonds. Because this failure does not occur during an initial reflow phase when the BGA is on the top side of the PCB, additional stresses due to gravitational pull are working in combination with these thermal stresses to break the bonds.

As a reflow process is performed and solder becomes molten, there is a limit to the amount of weight that can be put on a component before the retention force is exceeded and the part falls off the PCB. Before the parts falls off, it has been discovered that certain solder joints underneath the part open up. One remedy has been to avoid putting large parts or heavy parts underneath (on the bottom side of an assembly), but this can be limiting when circuit complexity demands components to be on both sides of a board.

Embodiments described herein include a negative gravity support plate that is configured to cancel out its own weight and the weight of a semiconductor chip such as a ball grid array (BGA) component. The weight of a semiconductor chip and the support plate may be called a cumulative weight. When pressed against a BGA component from below, the support plate may generate a negative force in an upwards direction greater than the cumulative weight. This negative applied pressure may result in a force that approximates the effect of gravity on the chip, so that the chip experiences an upward force equivalent to its weight.

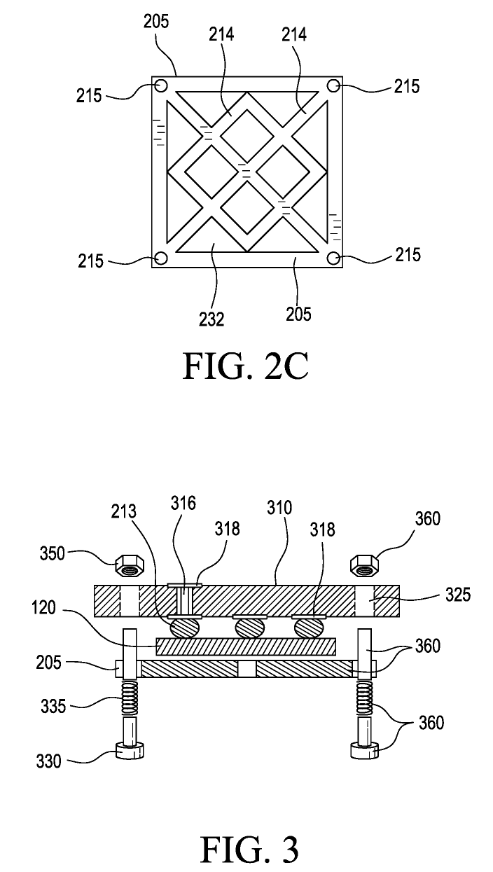

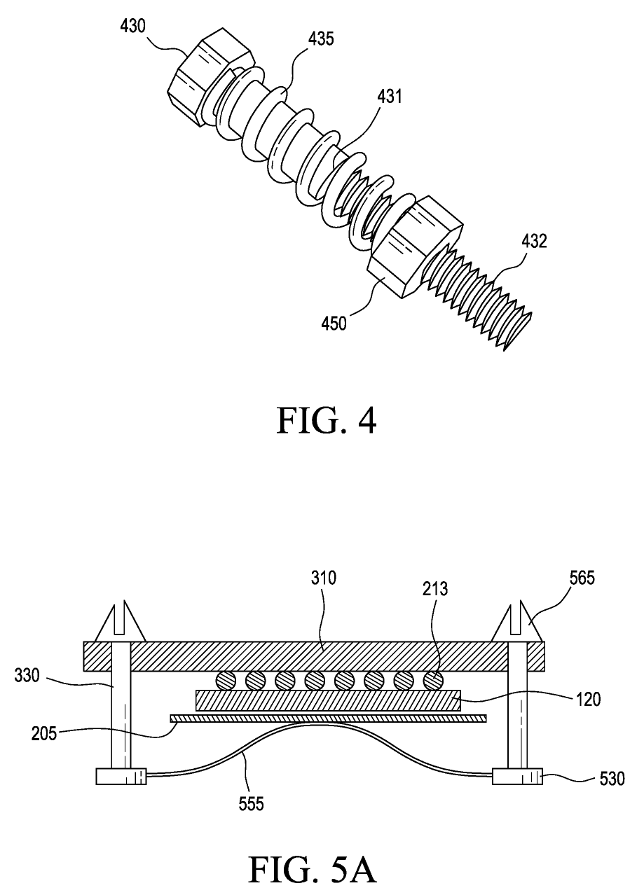

FIGS. 2A-2C illustrate top views of support plates in accordance with embodiments described herein. As illustrated in FIG. 2A, a support plate 205 is configured to extend past a periphery of a BGA package mounted thereon such that a plurality of bolts (illustrated in FIGS. 3 and 4) may be secured through bolt holes 215 in the support plate 205. The support plate 205 may include large apertures 230 that give the support plate 205 an appearance similar to that of a window frame. The use of a window frame design of the support plate 205 provides structural support throughout the BGA and substantial convection heat flow to the BGA during a reflow operation.

The support plate 205 may be made out of a material having low thermal mass. Several designs of the support plate may be used. FIG. 2A illustrates what may be known as a window or picture frame configuration. This picture frame configuration may have an outer border connected by substantially orthogonal members 212. FIG. 2B illustrates another design of a picture frame configuration in which an additional horizontal and additional vertical support beams 233 are provided. Apertures 231 may be smaller between the support beams and the picture frame illustrated in FIG. 2B may be able to contact the BGA 120 in more locations, and provide different support than the picture frame design illustrated in FIG. 2A. Alternatively, as illustrates in FIG. 2C, support beams 214 may be laid out in a substantially diagonal configurations forming different shaped apertures 232 within a rectangular support plate 205. The diagonal support beams 214 may allow the support plate 205 to support the BGA 120 in a different manner.

FIG. 3 illustrates a cross-sectional view of a PCB 310 and support plate 205 in accordance with embodiments described herein. A BGA 120 may be attached to the bottom of the PCB 310 with reflowed solder balls 213. There may also be a support assembly 360 including one of the support plates 205 illustrated in FIGS. 2A-2C, a set of retaining bolts 330 which pass through bolt holes 215 in the support plate 205 and through corresponding holes 325 in the PCB 310. The PCB 310 includes a number of via connections 316 and bond pads 318. The via connections 316 permit communication through upper and lower bond pads 318 between components near a top side or bottom side of the PCB 310 and components disposed in various layers of the PCB 310. The retaining bolts 330 may be secured on a top side of the PCB 310 by respective retaining nuts 350. The retaining nuts 350 secure the bolts 330 with resilient biasing springs 335 to the PCB 310. The retaining bolts 330 are threaded through the springs 335, and the springs 335 may resiliently urge or bias the support plate 205 against the BGA 120. The retaining bolts 330 may include a surface to receive a turning mechanism such as an Allen key or screw head to be turned into place.

According to embodiments described herein, a total of four retaining bolts 330 are used, one at each corner of the support plate 205, but the embodiments are not limited thereto. Alternative configurations may vary the position and quantity of retaining bolts used.

The support plate 205 may be secured to the PCB 310 by different mechanisms, including the spring 335. The spring 335 may be used to bias the support plate 205 against a semiconductor chip or BGA 120 that is mounted to an underside of the PCB 310 and hold the BGA 120 in place. An engineering calculation may take into account several factors to determine an appropriate spring 335 to be used and how much to compress the spring 335 against the negative gravity support plate 205 to hold the semiconductor chip in place.

The characteristics for the resilient biasing springs 335 used may be determined by the following criteria and formula:

FL=free length of spring (inches)

LL=load length of spring (length in assembled state, inches)

K=spring rate (lb/inch)

W_{bga}=weight of BGA (lb)

Wₛᵤₚ=weight of support plate

SF=spring force=(FL−LL)×K(spring deflection×spring rate)

For a particular BGA 120, the SF may be set equal to the total weight (W_{bga}+Wₛᵤₚ) divided by 4 (for 4 springs). The SF may neutralize a downward weight by the BGA 120. To push the BGA 120 upwards with an additional force substantially equal to the weight of the BGA chip 120, an additional W_{bga} may be used to determine the SF.

Based on the above variables, calculations are performed to determine a stand-off height of the retaining bolts 330 and a spring force of the springs 335 such that the end result may allow the spring force SF to cancel out the weight of the BGA 120 plus the support plate 205 to achieve a desired compensation against gravity.

Springs 335 may be selected to meet the spring force SF requirement at the required load length without bottoming out and having a diameter suitable for use with respective retaining bolts 330.

The spring force formula above may be used to determine a sizing of the springs 335 and the spring deflection. That calculation may take place depending on the weight of the BGA 120, and the weight of the support plate 205. To equal out the downward forces, the spring force of a selected spring 335 may be set equal to a weight of the BGA 120 plus the weight of the support plate 205. In order to produce a negative force to push a BGA 120 against the PCB 310 on a bottom side with the same weight that would be applied to a top side, the spring force SF of a selected spring may be set equal to substantially twice the weight of the BGA 120 plus the weight of the support plate 205 (i.e., 2×W_{bga}+Wₛᵤₚ). This latter spring force including twice the weight of the BGA 120 will push the BGA 120 in place during reflow thus lessening stress on solder balls 213 and bond pads 318. As a result the integrity of solder joints will be maintained.

The support plate 205 may be made to have sufficient apertures 230 between the support members such that the support plate 205 minimizes the impedance to convection or heating of the solder balls 213 and allows parts to reflow and form a proper joint. Materials for the support plate 205 may include a metal component such as aluminum or steel. Materials could include a polymer or other insulator that could withstand reflow temperatures on the order of 260 degrees Celsius on the order of ten minutes during a reflow operation. A thickness of the support plate may be designed to balance rigidity thereof in conjunction with thermal mass.

The support plate may be installed and removed during manufacture. After a first side of a PCB 310 is laden with chips and other circuit components, the PCB 310 may be turned over, and the support plate 205 affixed in place. The support plate 205 may also be applied before the PCB is turned over.

The support plate 205 may be used to secure multiple devices to a bottom side of the PCB 310. The support plate 205 may be fastened to the PCB 310 via pre-existing holes 325 in the PCB 310. For example, a PCB 310 may include a number of holes 325 that may be used during testing or in operation that may later be used to mount a heat sink to a BGA 120. If holes 325 are not immediately adjacent a BGA 120 to be secured with the support plate 205, the support plate 205 may be connected over a larger area and therefore more components than a target component may be supported. When making this determination regarding how much weight to support, proper springs 335 may be selected using the considerations described herein.

There may be multiple ways to attach the support plate 205 to the PCB 310 to fasten and remove the plate. In one embodiment, four corner retaining bolts 330 that thread into nuts on an opposite side of a PCB may be used. The retaining bolts 330 may use the aforementioned heat sink holes.

FIG. 4 illustrates a bolt 430 having a shoulder 431 and a spring 435 attached thereto in accordance with embodiments described herein. Once the size of the spring 435 is determined according to a method described herein, including the distance for the spring to be compressed, a bolt 430 with threaded length 432 and shoulder 431 distance is selected. In operation, once the bolts 430 are threaded through the nuts 450 to a point where they may bottom-out on the shoulder 431, the correct amount of deflection will be present in the springs 435 to achieve the negative gravity effect on the BGA 120 including twice the weight of the BGA 120. Embodiments described herein are designed to have a spring 435 having a known spring rate, and the bolt 430 may be defined to have a shoulder 431 give the correct deflection of the spring 435. Minimal torque would be involved to turn the bolts 430 the desired number of turns to achieve the coupling negative gravity effect. By doing so, BGA packages mounted to an underside of a PCB 310 may be supported and held in place during a reflow operation. The upward force provided by the spring 435 or other upward force biasing members described herein may prevent solder joint failure and other deleterious effects normally caused by unsupported BGA chips mounted to a bottom of a PCB 310 during reflow and upside down reflow.

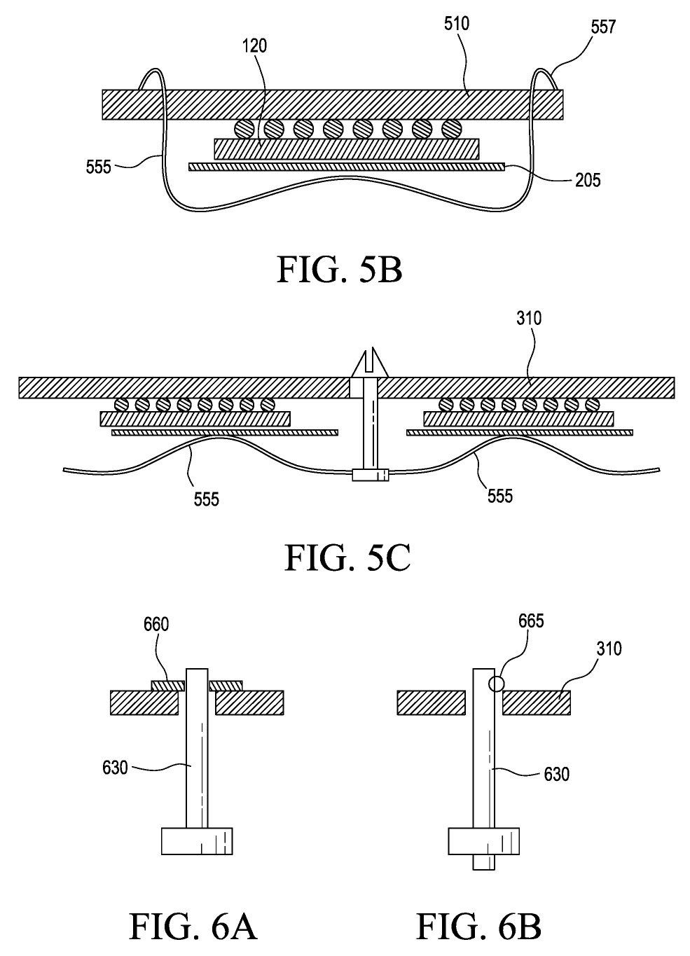

FIGS. 5A-5C illustrate embodiments of leaf spring biasing members in accordance with embodiments described herein. As illustrated in FIG. 5A, a leaf or diaphragm spring 555 may be fastened to bolts 530 or the like. The bolt members may be secured through a PCB 310 by various mechanisms such as a spring clip member 565. The bolts 530 may be threaded through holes in the PCB 510. To push a support plate 205 against the BGA 120, the bolts 530 are moved upwards resulting in the leaf spring 555 pressing against the support plate 205. Other fasteners may be used to fasten the support plate to a semiconductor chip. FIG. 5B illustrates an alternative embodiment in which a leaf spring 555 may be fastened with hook ends 557 through holes in the PCB 510. FIG. 5C illustrates multiple devices loaded by multiple support plates that may be biased by multiple leaf springs 555. The leaf springs 555 may be fastened to the PCB 510 in a manner described in embodiments herein. Weights of the leaf springs 555 and the BGA 120 may be used to select the proper leaf spring 555 to produce the upward negative gravity force as described herein.

FIGS. 6A and 6B illustrate additional fastening assemblies according to embodiments described herein. As illustrated in FIG. 6A, a pin 630 with a c-clip or cotter pin fastening member 660 may be used to press a support plate (not illustrated) against a semiconductor chip (also not illustrated), while still allowing resilient biasing by an appropriate spring or resilient member (not illustrated). FIG. 6B illustrates a pin 630 with quick release détente mechanism 665 that may be activated from below to hold the pin 630 in place within the PCB 310. An end of a pin may have other configurations such as a harpoon fastener that may be passed through a hole in a PCB 310 and extends outward when protruding through the hole.

Embodiments described herein describe the use of supporting hardware to create a negative gravity plate configured to cancel out a weight of a chip component and hardware, and generate a slight upwards pressure which corresponds to the normal force of gravity that the part would exert sitting on a horizontal surface, given some tolerance. In other words, the force needed to hold the component on the board in a negative direction, the negative direction being upwards. These upward forces may be used to counter the weight of a BGA chip on a bottom side of a PCB during reflow to prevent failure of solder joints, bonds, and/or pin failures that may succumb to the weight of the BGA in combination with thermal stresses during upside down reflow.

Tolerances and flexibilities may be designed into the embodiments described herein given a desire to bias the support plates slightly more or slightly less than the negative gravity amount depending on observations over the course of time.

What has been described are devices and methods to remedy the occurrence of failed Ball Grid Array solder connections due to the additional forces of gravity during a second phase reflow operation.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be effected while remaining within the spirit and scope of the invention. Accordingly, the foregoing disclosure, description, and figures are for illustrative purposes only and do not in any way limit the invention, which is defined only by the claims.

1. An apparatus configured to temporarily support a Ball Grid Array (BGA) component against a printed circuit board (PCB) during a manufacturing reflow operation, the apparatus comprising:
a support plate sized to fit over the BGA and having one or more mounting holes external to the periphery of the Ball Grid Array component;
a retaining member for each mounting hole, passing through said mounting hole;
a resilient biasing member for each retaining member,
wherein the resilient biasing member urges the support plate against the BGA component from below the BGA component such that the BGA component is urged against the PCB.

2. The apparatus of claim 1, wherein the support plate and BGA component create a cumulative weight, and wherein the support plate is urged against the BGA component with a force greater than the cumulative weight.

3. The apparatus of claim 1, wherein the resilient biasing member includes a spring.

4. The apparatus of claim 1, wherein the retaining member includes a bolt having a shoulder and the resilient member is mounted on the retaining member.

5. The apparatus of claim 1, wherein the retaining member is coupled to the PCB by a fastening member.

6. The apparatus of claim 1, wherein the support plate has the shape of a window frame.

7. The apparatus of claim 1, wherein the support plate includes a plurality of apertures to decrease thermal resistance thereof.

8. An apparatus to support a semiconductor chip mounted to a printed circuit board (PCB) during a manufacturing process thereof, the apparatus comprising:
a support plate configured to counter a weight of the semiconductor chip;
a plurality of fastening members on a first side of the PCB;
a plurality of support pins extending through the PCB and coupled to the plurality of fastening members; and
a biasing member connected to the plurality of support pins and configured to urge the support plate into contact with the semiconductor chip on a second side of the PCB.

9. The apparatus of claim 8, wherein the semiconductor chip is mounted to a bottom side of the PCB such that gravity pulls the semiconductor chip away from the PCB.

10. The apparatus of claim 8, wherein the biasing member urges the support plate and semiconductor chip upwards with a force greater than a gravitational force acting on the semiconductor chip.

11. The apparatus of claim 8, wherein the biasing member is a leaf spring.

12. The apparatus of claim 8, wherein the fastening members are C-clips or cotter pins.

13. The apparatus of claim 8, wherein the support plate has the shape of a window frame.

14. A method of mounting a BGA on a printed circuit board (PCB), comprising:
mounting a BGA on a side of a PCB;
determining a size of a resilient biasing member based on a weight of a support plate to be secured to the BGA; and
securing the support plate to the BGA and to the PCB using the resilient biasing member which is configured to urge the support plate against the BGA such that the BGA is urged against the PCB.

15. The method of claim 14, further comprising determining a negative gravity force to urge the support plate towards the PCB, wherein the negative gravity force is greater than the weight of the support plate and the BGA.

16. The method of claim 14, wherein securing the support plate to the BGA is performed using a retaining member.

17. The method of claim 16, wherein the retaining member includes a bolt having a shoulder wherein the resilient member is mounted on the retaining member.

18. The method of claim 14, wherein the support plate has the shape of a window frame.
